(19) United States
(12) Patent Application Publication
(10) Pub. No.: US 2021/0343548 A1
(43) Pub. Date: Nov. 4, 2021

(54) PACKAGE STRUCTURE AND METHOD FOR FORMING SAME

(71) Applicant: CHANGXIN MEMORY TECHNOLOGIES, INC., Hefei City (CN)

(72) Inventors: Jie LIU, Hefei (CN); Jun He, Hefei (CN); Changhao Quan, Hefei (CN); Zhan Ying, Hefei (CN)

(21) Appl. No.: 17/373,893

(22) Filed: Jul. 13, 2021

Related U.S. Application Data
(63) Continuation of application No. PCT/CN2021/075944, filed on Feb. 8, 2021.

(30) Foreign Application Priority Data
Feb. 19, 2020 (CN) 202010102446.0

(51) Int. Cl. H01L 21/56; H01L 23/498; H01L 23/00; H01L 23/31

(52) U.S. Cl. CPC H01L 21/563; H01L 21/565; H01L 23/49816; H01L 23/49838; H01L 24/16; H01L 2924/1811; H01L 2924/3511; H01L 2224/16225; H01L 2924/182; H01L 2924/1815; H01L 23/3107

(57) ABSTRACT

A package structure and a method for forming the same are provided. The package structure includes: a substrate, in which the substrate has a first surface and a second surface being opposite to the first surface, and has an opening penetrating through the first surface to the second surface of the substrate, the opening is in a long strip shape with a size at both two ends larger than a size at middle; a chip, in which the chip is fixed on the first surface of the substrate through solder bumps in a flipped over mode, and electrically connects with the substrate through the solder bumps, and the opening is located in a projection of the chip on the substrate; and a moulding compound wrapping the chip and filling the opening and a gap between the chip and the first surface of the substrate.

### CROSS-REFERENCE TO RELATED APPLICATION

The present application is a U.S. continuation application of International Application No. PCT/CN2021/075944, filed on Feb. 8, 2021, which claims priority to Chinese Patent Application No. 202010102446.0, filed on Feb. 19, 2020. International Application No. PCT/CN2021/075944 and Chinese Patent Application No. 202010102446.0 are incorporated herein by reference in their entireties.

### TECHNICAL FIELD

The disclosure relates to the field of chip packaging, and in particular to a package structure and a method for forming the same.

### BACKGROUND

After a chip is packaged, the resulted chip needs to be wrapped by injection molding, so as to protect the chip.

For a chip packaged by a process of flip chip, the chip is connected with a circuit on the substrate through a solder ball between the chip and the substrate. In a moulding process, a moulding compound is needed to wrap the whole chip and fill a gap between the chip and the substrate. The chip and the substrate are directly connected by the solder ball or other solder bumps, the gap therebetween is small and a distance between connection points is short. Therefore, air is not easy to exhaust when the moulding compound is filled, and a problem of unreliable package structure is prone to appearing.

In the related art, in order to facilitate gas exhausting during an injection molding process, multiple gas holes are provided on the packaging substrate, so that during the injection molding process, with filling of the moulding compound, gas is exhausted from the gas holes on the substrate. For a better gas exhausting effect, generally, multiple gas holes are formed in the substrate. However, since most areas of the substrate need to connected with the chip, the area of substrate which can be used to form the gas holes is very small, more gas holes are formed, which makes each gas hole is small in size. Although positions for exhausting gas are increased with the increase of the number of the gas holes, its improvement on the gas exhausting is limited as the gas holes with small size are prone to being blocked by the moulding compound.

In addition, a reliability of the package structure in which the above substrate is used is low, and the substrate often undergoes severe warping deformation, which will disconnect an electrical connection between the chip and the substrate, resulting in a disabled product.

Therefore, in the injection molding process, there is a need to solve the problem of how to avoid gas residue in the package structure, while avoiding the warpage of the substrate, thereby improving the reliability of the package structure.

### SUMMARY

A technical problem to be solved by the disclosure is to provide a package structure and a method for forming the same, and to improve a reliability of the package structure.

In order to solve the above problem, the disclosure provides a package structure, including a substrate, in which the substrate has a first surface and a second surface being opposite to the first surface, and has an opening penetrating through the first surface to the second surface of the substrate, the opening is in a long strip shape with a size at both two ends larger than a size at middle; a chip, in which the chip is fixed on the first surface of the substrate through solder bumps in a flipped over mode, and electrically connects with the substrate through the solder bumps, and the opening is located in a projection of the chip on the substrate; and a moulding compound, in which the moulding compound wraps the chip and fills up the opening and a gap between the chip and the first surface of the substrate.

The technical solution of the disclosure further provides a method for forming a package structure, the method includes following acts. A package chip is provided, the package chip includes a substrate and a chip fixed on the substrate, the substrate has a first surface and a second surface being opposite to the first surface, the above mentioned opening penetrating through the first surface and the second surface is formed in the substrate. The chip is fixed on the first surface of the substrate through solder bumps in a flip chip process, the solder bumps electrically connects with the substrate, and the opening in the substrate locates in a projection of the chip on the substrate. Injection molding treatment is executed on the package chip, a moulding compound wraps the chip and fills up the opening and a gap between the chip and the first surface of the substrate.

### BRIEF DESCRIPTION OF THE DRAWINGS

FIG. 1 is a schematic diagram of stress distribution when multiple gas holes are formed in a substrate.

FIGS. 2A to 2C are schematic structural diagrams of a package structure of a specific example of the disclosure.

FIG. 3 is a schematic diagram of a substrate of a package structure of a specific example of the disclosure.

FIG. 4 is a flow chart of a forming process of a package structure of a specific example of the disclosure.

### DETAILED DESCRIPTION

As described in background, a substrate is prone to warping when forming a chip packaged by a flip chip process in the related art, leading to a disabled product.

After carefully studying, the inventors found that in the related art, in order to facilitate exhausting gas in a package structure during an injection molding process, so that a moulding compound is able to fill up a space between the chip and the substrate, generally, multiple gas holes are formed in the substrate. However, since there are multiple gas holes in the substrate, uneven stress distribution is prone to occurring in the substrate. After the gas hole is filled with a moulding compound, due to a large difference in thermal expansion coefficients between the moulding compound and a material of the substrate, the substrate is prone to subjecting a stress applied by the moulding compound under a condition of temperature change. When there are multiple gas holes, the substrate between adjacent two of the gas holes and the substrate around a gas hole are subjected to different types of stresses, which is prone to leading to deformation of the substrate, thereby leading to a disabled product.

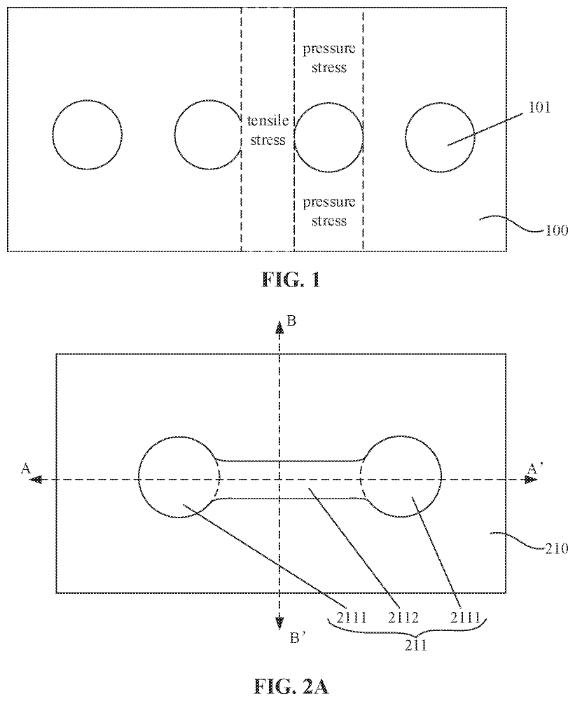

FIG. 1 is a schematic diagram of stress distribution when a substrate 100 has multiple gas holes 101.

An area of the substrate 100 between adjacent two of the gas holes 101 is subjected to a tensile stress, whereas an area of the substrate 100 around the gas hole 101 is subjected to a pressure stress.

In a process of patch assembly reflow soldering of the package structure, uneven distribution of internal stresses in the substrate 100 causes warping of the substrate 100, so that the binding between the substrate 100 and a solder bump of a chip is damaged, thereby leading to a disabled product.

To solve the above problem, the inventors provide a new package structure that allows a more uniform stress distribution of a substrate while exhausting gas during an injection molding process.

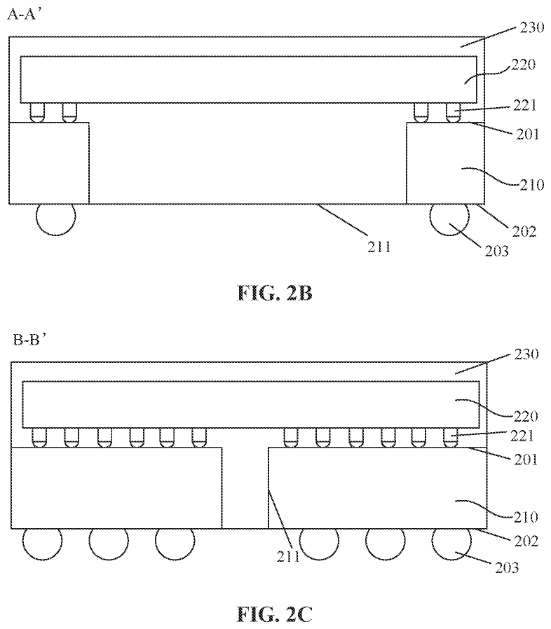

FIGS. 2A to 2C are schematic structural diagrams of a package structure of a specific example of the disclosure. FIG. 2A is a top view schematic diagram of a substrate of the package structure, FIG. 2B is a profile schematic diagram of the package structure along an A-A′ direction, and FIG. 2C is a profile schematic diagram of the package structure along a B-B′ direction.

In this specific example, the package structure includes a substrate 210, a chip 220 and a moulding compound 230.

The substrate 210 has a first surface 201 and a second surface 202 being opposite to the first surface 201, an opening 211 penetrating through the first surface 201 to the second surface 202 is formed in the substrate 210, the opening 211 is in a long strip shape, and a size at both two ends is larger than a size at middle. The substrate 210 is a circuit board. An electrical connection structure such as an interconnection circuit and a welding pad is formed on a surface and/or in an interior of the substrate 210, and are configured to form an electrical connection with the chip 220 and input electrical signals to the chip 220 or output electrical signals generated by the chip 220.

The chip 220 is fixed on the first surface 201 of the substrate 210 through solder bumps 221 in a flipped over mode and is electrically connected with the substrate 210 through the solder bumps 221. The solder bump 221 may be conductive bumps such as metal columns and solder balls, and the solder bump 221 is in contact with an electrical connection structure on the first surface of the substrate 210, so that the chip 220 is fixed on a surface of the substrate 210 and is electrically connect with the substrate 210. The chip 220 and the substrate 210 constitute a flip chip connection structure. The structure in FIG. 2 is only used as an example. Those skilled in the art may adopt an appropriate flip chip connection mode according to specific connection structures of a chip and a substrate.

The opening 211 is located in a projection of the chip 220 on the substrate 210, so that when the moulding compound 230 fills a gap between the chip 220 and the substrate 210, air can be exhausted from the opening 211.

The moulding compound 230 wraps the chip 220 and fills up the gap between the chip 220 and the first surface 201 of the substrate 210 and the opening 211. The moulding compound 230 protects the chip 220 and a connection part between the chip 220 and the substrate 210 from when the package structure is subjected to external impact.

The moulding compound 230 only covers the first surface 201 of the substrate 210, and exposes the second surface 202 of the substrate 210. A pin or a welding pad is formed on the second surface 202 as a contact point to form an electrical connection between the package structure and other components.

In this specific example, a solder ball 203 is formed on the second surface 202 of the substrate 210. The solder ball 203 is formed on the pin or the welding pad on the second surface 202 of the substrate 210, and an electric connection is formed between the solder ball 203 and the electric connection structure in the substrate 210. The solder ball 203 may be a lead-containing tin ball or a lead-free tin ball, etc. The package structure may be mounted to other electronic components such as other circuit boards by the solder ball 203 through a reflow soldering process.

Referring to FIG. 2A, in this specific example, only one opening 211 is formed in the substrate 210, the opening 211 is in a long strip shape with a size at both two ends larger than a size at middle.

In this specific example, the opening 211 includes two first sub-openings 2111 and a second sub-opening 2112. The two first sub-openings 2111 are located at the two ends, respectively, and the second sub-opening 2112 connects with the two first sub-openings 2111. A cross sections of the first sub-openings 2111 in a direction parallel to the surface of the substrate 210 are circles, and a cross section of the second sub-opening 2112 in the direction parallel to the surface of the substrate 210 is a long strip with a uniform width distance. A range of the diameter of the first sub-openings 2111 is 1 mm to 5 mm, and a range of the width of the second sub-opening 2112 is 500 μm-2 mm. A range of the length of the opening 211 is 5 mm to 12 mm, which is conducive to exhausting gas rapidly and avoiding the opening 211 being blocked too early by the moulding compound in an injection molding process, so that the opening 211 has a better gas exhausting effect. Apertures of the first sub-openings 2111 are large, which are conducive to exhausting the gas rapidly; the second sub-opening 2112, which has a long length and a small and uniform width, is conducive to dispersing a stress applied by the moulding compound in the opening 211 on the substrate 210, and improving a uniformity of stress distribution throughout the substrate 210.

In addition, in this specific example, the connection at the edge of the first sub-openings 2111 and the second sub-opening 2112 is arc, forming an arc corners, so that all edges of a cross section of the opening 211 are smooth lines without sharp corner structures, thereby avoiding concentration of stresses at corners.

The opening 211 is arranged along a symmetric axis (A-A′) of the substrate 210 and is symmetric about the symmetric axis so that a stress exerted on the substrate 210 by the opening 211 and the moulding compound 230 filled inside it is symmetrically distributed on both sides. Welding areas of the substrate 210 are located on both sides of the opening 211, and the solder bump 221 of the chip 220 are welded on the welding areas of the substrate 210.

In other specific examples, the cross section of the first sub-openings may further be at least one of semicircle, ellipse, rectangle or polygon; the second sub-opening is a long strip with different widths different at different positions, but preferably, the width of all positions of the second sub-opening are same; and the maximum width of the first sub-opening in a direction perpendicular to a length of the opening is larger than the width of the second sub-opening. The second sub-opening has a small width and a large length-width ratio is large, and connects with the first sub-openings as a whole, which may reduce a stress exerted on the substrate an improve a uniformity of stress distribution in the substrate as compared with a smaller opening such as a circular hole so that the substrate remains flat under a high temperature environment, thereby ensuring the electrical connection between the flip chip and the substrate.

The aperture of the first sub-opening is large, which is conducive to exhausting gas rapidly, making the opening not prone to being blocked in the injection molding process, and improving the gas exhausting effect. When the widths of all positions of the second sub-opening are same, and the cross section of the first sub-openings are circles, the uniformity of the stress distribution may be further improved.

In some specific examples, in the direction perpendicular to the length of the opening, a range of the maximum width of the first sub-openings is 1 mm to 5 mm, and a range of the maximum width of the second sub-opening is 500 μm to 2 mm.

In another specific example, when the chip has is a large size and the corresponding substrate also has a large size, strength of the substrate may be affected only one opening with a large length is formed for exhausting the gas.

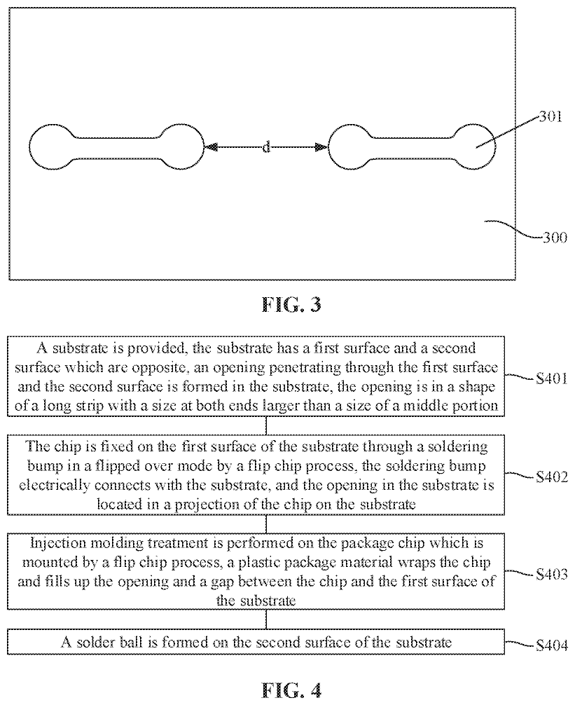

FIG. 3 is a top view schematic diagram of a substrate of a package structure of another specific example of the disclosure.

In this specific example, two openings 301, which extend in a same length direction and locate in a same straight line, are formed in a substrate 300. In order to avoid an increase of uneven stress distribution at different positions of the substrate 300 caused by the two openings 301, the two openings 301 has a large distance, and preferably, a distance d between adjacent two of the openings is greater than 3 mm.

In other specific examples, the number of the openings in the substrate to which each chip corresponds may also be reasonably arranged according to the size of the chip and the substrate. On the premise of satisfying a strength of the substrate, only one opening is formed on the substrate to which each chip corresponds, which may minimize a stress exerted on the substrate and improve a uniformity of the stress distribution.

Referring to FIGS. 2B and 2C, the moulding compound 230 not only fills up the opening 211 but also may spill over to the second surface 202 of the substrate 210 to form a moulding compound convex strip 231 protruding from the second surface 202 of the substrate 210. The moulding compound convex strip 231 also covers a part of the second surface of the substrate 210 to ensure that the opening 211 is completely closed. The moulding compound convex strip 231 is connected to the moulding compound 230 on the first surface of the substrate 210 to further improve a bonding strength between the moulding compound 230 and the substrate 210.

According to the package structure of the disclosure, an opening in a long strip shape with a size at both two ends larger than a size at middle is formed in the substrate, which may avoid being blocked by the moulding compound too early during injection molding and improve an efficiency of exhausting gas. The opening is in the long strip shape, which may improve the uniformity of stress distribution in the substrate, avoid warping deformation of the substrate under the high temperature environment, keep the substrate flat, and ensure a reliability of an electrical connection between the chip and the substrate.

A specific example of the disclosure further provides a method for forming the above package structure.

FIG. 4 is a flow chart of a forming process of a package structure of a specific example of the disclosure.

The method for forming the package structure includes the following acts.

At S401: a substrate is provided, the substrate has a first surface and a second surface being opposite to the first surface, an opening penetrating through the first surface and the second surface is formed in the substrate, the opening is in a long strip shape with a size at both two ends larger than a size at middle.

The substrate may be a circuit board. An electrical connection structure such as an interconnection circuit and a welding pad is formed on a surface and/or in an interior of the substrate. The opening in the substrate is in a long strip shape and penetrates the substrate.

Preferably, the opening is arranged along a symmetric axis of the substrate and is arranged symmetrically about the symmetric axis. A range of a length of the opening is 5 mm to 12 mm so that the opening has a high gas exhausting efficiency.

The opening includes two first sub-openings located at the both two ends and a second sub-opening connecting with the two first sub-openings. A cross section of the first sub-openings has a shape of circle, semicircle, ellipse, rectangle or polygon, and the second sub-opening is a long strip with a uniform width; and the maximum width of the first sub-opening in a direction perpendicular to a length of the opening is larger than the width of the second sub-opening.

A range of the maximum width of the first sub-opening is 1 mm to 5 mm, and a range of the maximum width of the second sub-opening is 500 μm to 2 mm.

An edge of a cross section of the opening is smooth, to avoid stress accumulation at a sharp morphology of an opening edge.

In other specific examples, two or more openings, which extend in a same length direction and locate in a same straight line, are formed in a substrate corresponding to a single chip, and a distance between adjacent two of the openings is greater than 3 mm.

At S402: the chip is fixed on the first surface of the substrate through solder bumps in a flipped over mode by a flip chip process, the solder bumps electrically connects with the substrate, and the opening in the substrate is located in a projection of the chip on the substrate.

At S403: injection molding treatment is executed on the package chip which is mounted by a flip chip process, a moulding compound wraps the chip and fills up the opening and a gap between the chip and the first surface of the substrate.

The substrate, on which a chip is mounted by a flip chip process, may be placed in a cavity of an injection mold, and the second surface of the substrate is located on the bottom surface of the cavity; and the moulding compound in the liquid state is injected into the cavity and then solidified, The moulding compound fills up the cavity, wraps the chip and fills the gap between the chip and the surface of the substrate.

Specifically, in a specific example, a method of executing the injection molding treatment on the package chip includes following acts. The injection mold is provided. The injection mold includes a base plate and a cover, the cover is configured to cover on the base plate and form a cavity between the cover and the base plate. The package chip is placed in the cavity. The substrate is placed on a surface of the base plate. The moulding compound in the liquid state is injected into the cavity until the moulding compound in the liquid state fills up the cavity. Heat treatment is executed to solidify the moulding compound in the liquid state. The package chip wrapped by the solidified moulding compound is taken out from the cavity.

A groove connecting with the opening in the substrate may be formed in the surface of the base plate on a bottom of the cavity, and connects with an exterior of the package mold. During injecting the moulding compound, gas in the cavity is exhausted through at least part of the openings. After moulding compound filling is completed, the moulding compound fills up the opening and spills over to the second surface of the substrate to form a moulding compound convex strip protruding from the second surface of the substrate.

The opening with a large length is not prone to being completely blocked by the moulding compound, so it can be continuously configured as a gas exhausting channel before the moulding compound completely fills up the cavity. In addition, aperture of the both two ends of the opening is larger than that at middle, which can maintain a fast gas exhausting speed.

In a specific example, at least one opening hole is formed on the cover, and connects the cavity with the outside; and the moulding compound in the liquid state is injected into the cavity though the at least one opening hole. In another specific example, at least two opening holes are formed on the cover, and the method further includes: in a process of the injection molding treatment, the moulding compound in the liquid state is injected through at least one opening hole, and gas in the cavity is exhausted to the outside through at least one opening hole.

At S404: a solder ball is formed on the second surface of the substrate.

After the injection molding treatment is completed, the solder ball is formed on the second surface of the substrate. The solder ball may be a lead-containing tin ball or a lead-free tin ball, etc. Subsequently, the package structure may be mounted to other electronic components such as other circuit boards by the solder ball 203 through a subsequent reflow soldering process.

According to the above method for forming the package structure, in an injection molding process, gas in the package structure may be exhausted through the opening on the substrate, and the opening has a large aperture is in a long strip shape, which may maintain a high gas exhausting efficiency. Further, the opening is in the long strip shape, which may improve a uniformity of stress distribution in the substrate, avoid warping deformation of the substrate under a high temperature environment, keep the substrate flat, and ensure a reliability of an electrical connection between the chip and the substrate.

The above are only preferred examples of the disclosure, and it should be noted that, without deviating from the principle of the disclosure, a number of improvements and refinements may be made by those skilled in the art, and these improvements and refinements shall also be regarded as the protection scope of the disclosure.

1. A package structure, comprising:
a substrate, wherein the substrate has a first surface and a second surface being opposite to the first surface, and has an opening penetrating through the first surface to the second surface of the substrate, the opening is in a long strip shape with a size at both two ends larger than a size at middle;
a chip, wherein the chip is fixed on the first surface of the substrate through solder bumps in a flipped over mode, and electrically connects with the substrate through the solder bumps, and the opening is located in a projection of the chip on the substrate; and
a moulding compound, wherein the moulding compound wraps the chip and fills up the opening and a gap between the chip and the first surface of the substrate.

2. The package structure of claim 1, wherein the opening is arranged along a symmetric axis of the substrate.

3. The package structure of claim 1, wherein the opening comprises two first sub-openings located at both two ends and a second sub-opening located at middle, and the second sub-opening connects with the two first sub-openings.

4. The package structure of claim 3, wherein a cross section of the first sub-openings has a shape of circle, semicircle, ellipse, rectangle or polygon, and the second sub-opening has a long strip shape with a uniform width; and a maximum width of the first sub-opening in a direction perpendicular to a length of the opening is larger than the width of the second sub-opening.

5. The package structure of claim 4, wherein a range of the maximum width of the first sub-openings is 1 mm to 5 mm, and a range of a maximum width of the second sub-opening is 500 μm to 2 mm.

6. The package structure of claim 1, wherein an edge of a cross section of the opening is smooth.

7. The package structure of claim 1, wherein the substrate comprises two or more openings which extend in a same length direction and locate in a same straight line, and a distance between adjacent two of the openings is greater than 3 mm.

8. The package structure of claim 1, wherein a range of a length of the opening is 5 mm to 12 mm.

9. The package structure of claim 1, wherein the moulding compound fills up the opening and spills over to the second surface of the substrate to form a moulding compound convex strip protruding from the second surface of the substrate.

10. The package structure of claim 1, further comprising a solder ball formed on the second surface of the substrate.

11. A method for forming a package structure, comprising:
providing a package chip, wherein the package chip comprises a substrate and a chip fixed on the substrate; the substrate has a first surface and a second surface being opposite to the first surface, and has the opening penetrating through the first surface and the second surface as defined in claim 1 formed in the substrate; the chip is fixed on the first surface of the substrate through solder bumps by a flip chip process, the solder bumps electrically connect with the substrate, and the opening in the substrate is located in a projection of the chip on the substrate; and
executing an injection molding treatment on the package chip, a moulding compound wrapping the chip and filling up the opening and a gap between the chip and the first surface of the substrate.

12. The method of claim 11, wherein during the injection molding treatment, gas in the package structure is exhausted through at least one of the openings.

13. The method of claim 12, wherein a process of executing the injection molding treatment on the package chip comprises: providing an injection mold, the injection mold comprising a base plate and a cover, the cover being configured to cover on the base plate and form a cavity between the cover and the base plate; placing the package chip in the cavity, the substrate being placed on a surface of the base plate; injecting the moulding compound in a liquid state into the cavity until the moulding compound in the liquid state fills up the cavity; executing a heat treatment to solidify the moulding compound in the liquid state; and taking out the package chip wrapped by a solidified moulding compound from the cavity.

14. The method of claim 13, wherein at least one opening hole is formed on the cover and connects the cavity with outside; and the moulding compound in the liquid state is injected into the cavity though the at least one opening hole.

15. The method of claim 14, wherein at least two opening holes are formed on the cover, and the method further comprises during the injection molding treatment, exhausting gas in the cavity to the outside through at least one of the opening holes.

16. The method of claim 11, wherein the moulding compound fills up the opening and spills over to the second surface of the substrate to form a moulding compound convex strip protruding from the second surface of the substrate.

17. The method of claim 11, further comprising: forming a solder ball on the second surface of the substrate.
